(19) United States
(12) Patent Application Publication
(10) Pub. No.: US 2015/0176819 A1
(43) Pub. Date: Jun. 25, 2015

(54) METAL COPPER CLAD LAMINATE AND METHOD OF MANUFACTURING THE SAME

(71) Applicant: SAMSUNG ELECTRONICS CO., LTD., Suwon-si (KR)

(72) Inventors: Young Kyung KIM, Suwon-si (KR); Jae Wook KWON, Seoul (KR); Seog Ho LIM, Seongnam-si (KR); Seok Chan HONG, Seongnam-si (KR)

(73) Assignee: SAMSUNG ELECTRONICS CO., LTD.

(21) Appl. No.: 14/472,092

(22) Filed: Aug. 28, 2014

(30) Foreign Application Priority Data
Dec. 19, 2013 (KR) 10-2013-0159255

(51) Int. Cl. F21V 19/00; H05K 3/00; F21V 29/89; H05K 1/05; F21V 21/00; H05K 3/10; H05K 3/38

(52) U.S. Cl. CPC F21V 19/0025; H05K 3/10; H05K 3/0079; H05K 3/0011; H05K 3/38; H05K 1/05; F21V 21/00; F21V 29/89

(57) ABSTRACT

A metal copper clad laminate (MCCL) includes a metal base, an insulating layer and a copper foil. The metal base has at least one recess defined in one surface thereof. The insulating layer is laminated on the one surface of the metal base and has a first opening exposing the at least one recess. The copper foil is laminated on the insulating layer and has a second opening exposing the at least one recess and the first opening.

### CROSS-REFERENCE TO RELATED APPLICATION

This application claims benefit of priority to Korean Patent Application No. 10-2013-0159255 filed on Dec. 19, 2013, with the Korean Intellectual Property Office, the entire content of which is incorporated herein by reference.

### TECHNICAL FIELD

The present disclosure relates to a metal copper clad laminate (MCCL) and a method of manufacturing the same.

### BACKGROUND

In mounting an electronic component having a high heating value, such as a light emitting device using a light emitting diode (LED), a metal-core printed circuit board (MCPCB) is generally employed in order to effectively dissipate heat generated by the electronic component therethrough.

An MCPCB is manufactured by etching a copper foil of an MCCL. An MCCL is manufactured by stacking an insulating layer and a copper foil to be used as a circuit on a metal plate, and here, the insulating layer interposed between the metal plate and the copper foil interferes with smooth heat transmission.

Also, the application of such an MCCL to a package module increases the size of the package module, thereby limiting miniaturizability thereof.

### SUMMARY

An aspect of the present disclosure may provide a metal copper clad laminate (MCCL) contributing to a reduction in a size of a package module when applied thereto, while enhancing heat dissipation efficiency thereof.

However, objects of the present disclosure are not limited thereto and objects and effects that may be recognized from technical solutions or embodiments described hereinafter may also be included while not being explicitly mentioned.

One aspect of the present disclosure relates to a metal copper clad laminate (MCCL) including a metal base, an insulating layer and a copper foil. The metal base has at least one recess defined in one surface thereof. The insulating layer is laminated on the one surface of the metal base and has a first opening exposing the at least one recess. The copper foil is laminated on the insulating layer and has a second opening exposing the at least one recess and the first opening.

The first opening may have shape and size substantially corresponding to shape and size of a region opened from the one surface of the at least one recess.

The second opening may have a shape substantially corresponding to a shape of the first opening.

The recess may have a cup structure in which inner surfaces of the at least one recess are sloped toward a bottom surface thereof.

The metal copper clad laminate may further include a reflective layer covering a surface of the at least one recess.

The reflective layer may be at least one of an Ag thin film, an Al thin film, and a TiO₂ thin film.

The metal base may be a copper plate.

The copper foil may have a size smaller than a size of the insulating layer, and expose the insulating layer along the circumferential edges of the copper foil.

Another aspect of the present disclosure encompasses a method of manufacturing a metal copper clad laminate (MCCL) including forming at least one recess on one surface of a metal base. An insulating layer is formed on the one surface of the metal base to have a first opening allowing the at least one recess to be exposed therethrough. A copper foil is formed on the insulating layer to have a second opening allowing the at least one recess and the first opening to be exposed therethrough.

The metal base may be a copper plate.

In the forming of at least one recess, a surface of the metal base may be partially etched to a depth.

In the forming of the insulating layer, a mask may be disposed covering the recess on the one surface of the metal base, and an insulating material may be applied to the mask to print the insulating material.

The first opening may have shape and size substantially corresponding to shape and size of an open region of the recess, and the second opening may have a shape substantially corresponding to a shape of the first opening.

The method may further include: coating a reflective layer to cover a surface of the at least one recess.

The method may further include: exposing the insulating layer along circumferential edges of the copper foil.

Still another aspect of the present disclosure relates to a light source module having a chip on board (COB) type structure including a board, a light emitting device and an encapsulator. The board as the above-described MCCL. The light emitting device is disposed in direct contact with an exposed portion of the at least one recess of the MCCL. The encapsulator is disposed on the light emitting device.

The light source module may further include a photo solder resist (PSR) coated on the copper foil of the MCCL. An exposed portion of the copper foil not coated with the PSR may define electrode pads that are electrically connected to the light emitting device.

Still another aspect of the present disclosure encompasses a method of manufacturing a metal copper clad laminate (MCCL) including laminating an insulating layer on a metal base that has at least one recess and forming a first opening in the insulating layer to expose the at least one recess through the first opening. A copper foil is laminated on the insulating layer and a second opening is formed in the copper foil to expose the at least one recess and the first opening through the second opening. The copper foil and the insulating layer are bonded through hot pressing.

The method of manufacturing MCCL may include exposing the insulating layer along circumferential edges of the copper foil before the hot pressing.

The method of manufacturing MCCL may include exposing the insulating layer along circumferential edges of the copper foil after the hot pressing.

### BRIEF DESCRIPTION OF DRAWINGS

The above and other aspects, features and other advantages of the present disclosure will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is a plan view schematically illustrating a metal copper clad laminate (MCCL) according to an example embodiment of the present inventive concept.

FIG. 2A is a perspective view schematically illustrating the MCCL of FIG. 1.

FIG. 2B is a cross-sectional view taken along line X-X of FIG. 1.

FIGS. 3A and 3B are a plan view and a cross-sectional view schematically illustrating a modified example of the MCCL of FIG. 1.

FIG. 4A is a plan view schematically illustrating an MCCL according to another example embodiment of the present inventive concept.

FIG. 4B is a cross-sectional view taken along line X-X of FIG. 4A.

FIGS. 5A through 9 are views schematically illustrating sequential processes of a method of manufacturing an MCCL according to an example embodiment of the present inventive concept.

FIG. 10 is a perspective view schematically illustrating an example of a light source module using an MCCL according to various example embodiments of the present inventive concept.

FIG. 11 is a cross-sectional view of the MCCL of FIG. 10.

FIG. 12 is an enlarged view of portion “A” of FIG. 11.

FIG. 13 is a perspective view schematically illustrating a lighting device according to an example embodiment of the present inventive concept.

### DETAILED DESCRIPTION

Hereinafter, example embodiments of the present inventive concept will be described in detail with reference to the accompanying drawings.

The disclosure may, however, be example in many different forms and should not be construed as being limited to the specific example embodiments set forth herein. Rather, these example embodiments are provided so that this disclosure will be thorough and complete, and will fully convey the scope of the disclosure to those skilled in the art.

In the drawings, the shapes and relative dimensions of elements may be exaggerated for clarity, and the same or like reference numerals will be used throughout to designate the same or like elements.

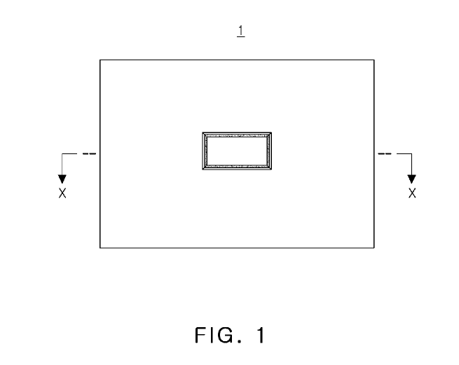

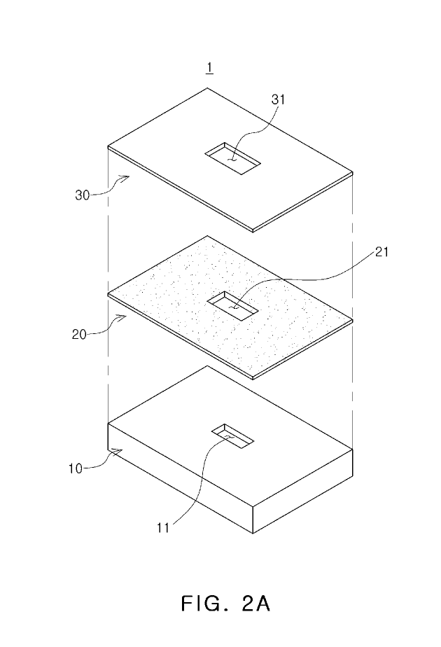

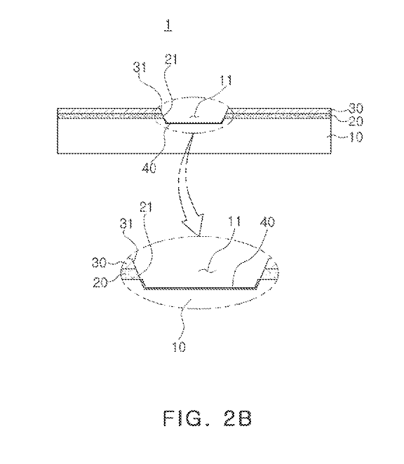

A metal copper clad laminate (MCCL) according to an example embodiment of the present inventive concept will be described with reference to FIGS. 1 and 2. FIG. 1 is a plan view schematically illustrating a metal copper clad laminate (MCCL) according to an example embodiment of the present inventive concept. FIG. 2A is a perspective view schematically illustrating the MCCL of FIG. 1, and FIG. 2B is a cross-sectional view taken along line X-X of FIG. 1.

Referring to FIGS. 1 and 2, the MCCL 1 according to an example embodiment of the present inventive concept may include a metal base 10, an insulating layer 20 laminated on the metal base 10, and a copper foil 30 laminated on the insulating layer 20.

The metal base 10 may be a copper plate formed of copper (Cu) having excellent heat conductivity and may have a quadrangular structure having a prescribed size (for example, 500 mm×600 mm). According to an example embodiment of the present inventive concept, the metal base 10 may be formed of a material other than copper. For example, the metal base 10 may be formed of aluminum (Al). In an example embodiment of the present inventive concept, a copper plate may be used as the metal base 10.

The metal base 10 may have at least one recess 11 formed in one surface, for example, an upper surface, thereof. The recess 11 may be formed to have a cup shaped structure in which inner surfaces thereof are sloped or inclined toward a bottom surface (see FIG. 2B). Alternatively, the recess 11 may have a step structure in which the inner surfaces thereof are perpendicular to the bottom surface.

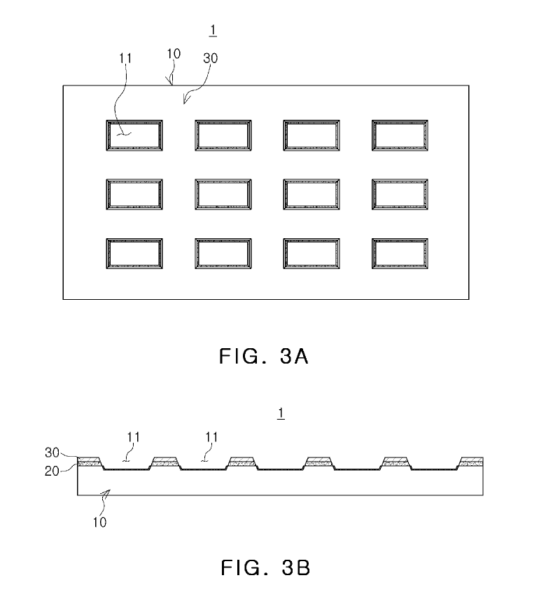

A single recess 11 may be provided. Alternatively, a plurality of recesses 11 may be provided as illustrated in FIGS. 3A and 3B. In this case, the recesses 11 may be arranged in rows and columns.

The recess 11 may be formed through, for example, etching. Alternatively, the recess 11 may also be formed through any other method such as mechanical machining.

A reflective layer 40 may be formed to cover a surface of the recess 11. The reflective layer 40 may be a thin film formed by applying at least one of silver (Ag), aluminum (Al), and TiO₂. When a light emitting diode (LED) chip is mounted in the recess 11, light may be reflected through the reflective layer 40 to enhance light emission efficiency. The reflective layer 40 may be optional. Thus, the reflective layer 40 may be omitted according to an example embodiment of the present inventive concept. In an example embodiment of the present inventive concept, the reflective layer 40 may be basically provided on a surface of the recess 11.

The insulating layer 20 may be laminated on one surface of the metal base 10 and have a shape substantially corresponding to a shape of the metal base 10.

The insulating layer 20 may be formed of an epoxy-based resin. In this case, the insulating layer 20 may contain a filler in an amount of approximately 60% to 80% to enhance heat conductivity, and have a thickness ranging from 80 μm to 100 μm to secure dielectric properties.

The insulating layer 20 may be formed of a polyimide resin resistant to brittleness. In this case, damage to the insulating layer 20 to drop foreign objects or generate burr in a cut section during a pressing operation may be prevented.

Referring to FIG. 2B, the insulating layer 20 may have a first opening 21 that exposes the recess 11. The opening 21 may have shape and size substantially corresponding to shape and size of an open region of the recess 11 in one surface. For example, when the recess 11 has a quadrangular shape, the first opening 21 may also have a quadrangular shape corresponding thereto.

Also, the first opening 21 may have a size substantially corresponding to or greater than a size of the open region of the recess 11 such that the insulating layer does not cover the recess 11. Thus, although the insulating layer 20 is laminated on one surface of the metal base 10, the recess 11 of the metal base 10 may be exposed upwardly through the first opening 21 of the insulating layer 20.

The first opening 21 may be provided to correspond to the number of recesses 11. In the drawings, for example FIG. 2B, it is illustrated that a single first opening 21 is provided, but the present disclosure is not limited thereto. Namely, when a plurality of recesses 11 are provided, a plurality of first openings 21 may be provided corresponding to the plurality of recesses 11.

The copper foil 30 may be laminated on the insulating layer 20. Also, like the insulating layer 20, the copper foil 30 may have a shape substantially corresponding to that of the metal base 10. The copper foil 30 may constitute circuit wirings of a metal-core printed circuit board (MCPCB) through a patterning process later.

The copper foil 30 may have a second opening 31 exposing the recess 11 and the first opening 21. The second opening 31 may have a shape substantially corresponding to a shape of the first opening 21. For example, when the recess 11 has a quadrangular shape, the second opening 31 may have a quadrangular shape, like the first opening 21. Without being limited to the quadrangular shape, the second opening 31 may have various other shapes as long as they expose the first opening 21.

The second opening 31 may have a size corresponding to at least a size of the first opening 21 such that the copper foil 30 does not cover the first opening 21. For example, the second opening 31 may be greater than the first opening 21. Thus, although the copper foil 30 is laminated on the insulating layer 20, the first opening 21 and the recess 11 may be exposed upwardly through the second opening 31 of the copper foil 30.

Like the first opening 21, the second opening 31 may be provided to correspond to the number of the recesses 11. In the drawings, for example FIG. 2B, a single second opening 31 is illustrated, but the present disclosure is not limited thereto. Namely, when the recess 11 is provided in plural, the second opening 31 may also be provided in plural corresponding to the plural recesses 11.

The MCCL 1 may be used as an MCPCB for the purpose of a chip-on-board (COB) through a patterning process performed on the copper foil 30. In particular, the MCCL 1 according to an example embodiment of the present inventive concept may have the recess 11 exposed through the first and second openings 21 and 31, and the recess 11 may be provided as a mounting area for mounting a light emitting device therein, for example. Namely, a bottom surface of the recess 11 may define a mounting surface, and the sloped lateral surfaces of the recess 11 may define reflective surfaces.

Since the light emitting device is mounted on and in direct contact with the metal base 10, heat of the light emitting device may be totally dissipated through the metal base 10 externally. Thus, heat dissipation efficiency may be improved, compared to the related art.

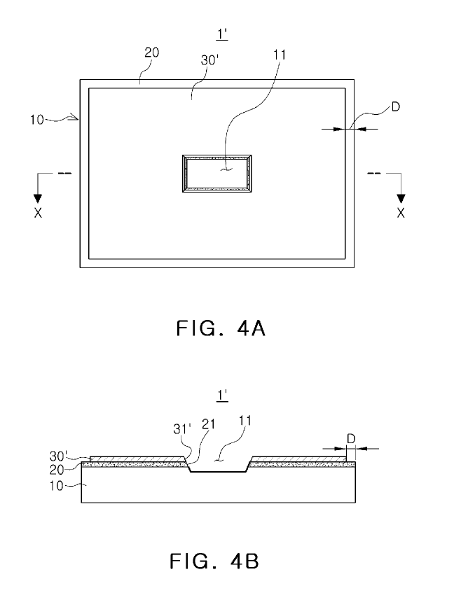

FIGS. 4A and 4B schematically illustrate a metal copper clad laminate (MCCL) 1′ according to another example embodiment of the present inventive concept.

Basically, the MCCL 1′ according to the example embodiment illustrated in FIGS. 4A and 4B have a configuration substantially identical to that of the example embodiment illustrated in FIGS. 1 through 3, except for a structure of copper foil. Thus, redundant descriptions of the portions identical to those of the example embodiment illustrated in FIG. 1 will be omitted and the configuration of the copper foil will be mainly described.

FIG. 4A is a plan view schematically illustrating an MCCL according to another example embodiment of the present inventive concept, and FIG. 4B is a cross-sectional view taken along line X-X of FIG. 4A.

As illustrated in FIGS. 4A and 4B, the MCCL 1′ according to an example embodiment of the present inventive concept may include a metal base 10, an insulating layer 20 laminated on the metal base 10, and a copper foil 30′ laminated on the insulating layer 20.

The metal base 10 may be formed of, for example, a copper plate, and may have a quadrangular shape having a desired size. A recess 11 having a cup shaped structure may be provided in an upper surface of the metal base 10.

The insulating layer 20 may be laminated on an upper surface of the metal base 10. The insulating layer 20 may have a quadrangular shape substantially corresponding to a shape of the metal base 10.

The insulating layer 20 may have the first opening 21 exposing the recess 11. The first opening 21 may have shape and size substantially corresponding to shape and size of the region opened from one surface of the recess 11. The first opening 21 may have a size substantially corresponding to a size of the open region of the recess 11 not to cover the recess 11.

The copper foil 30′ may be laminated on the insulating layer 20. The copper foil 30′ may have a quadrangular shape corresponding to shapes of the metal base 10 and the insulating layer 20 and have a size smaller than a size of the insulating layer 20. Thus, the insulating layer 20 may be partially exposed along the circumferential edges of the copper foil 30′. Namely, when viewed from above, the copper foil 30′ may be surrounded by the exposed insulating layer 20.

Referring to FIG. 4A, an interval between edges of the copper foil 30′ and edges of the insulating layer 20 may be defined as an insulation distance D preventing an electrical connection between the copper foil 30′ and the metal base 10 (in detail, the insulation distance may be defined by the sum of the intervals between the edges of the copper foil 30′ and the edges of the insulating layer 20 and a thickness of the insulating layer 20, but here, since the thickness of the insulating layer 20 is very small, relatively to the interval between the edges, so it is negligible). The insulation distance D may be adjusted within a range of 1 mm to 15 mm. By securing the sufficient insulation distance between the copper foil 30′ and the metal base 10, testing of a withstand voltage may be stably performed. In an example embodiment of the present inventive concept, the range of the insulation distance D may be defined as 15 mm or less. In this case, although the range of insulation distance D exceeding 15 mm has no problem in testing a withstand voltage, loss of a raw material is increased, thereby increasing manufacturing costs.

Similarly, the copper foil 30′ may have a second opening 31′ exposing the recess 11 and the first opening 21. The second opening 31′ may have a shape corresponding to that of the first opening 21.

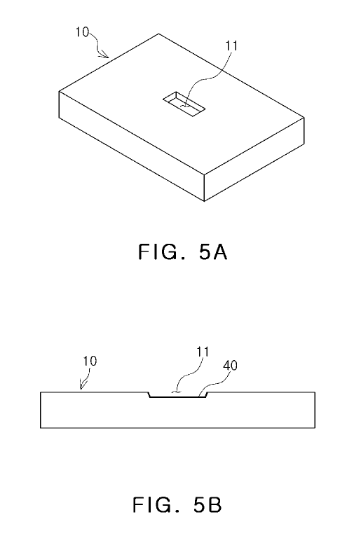

A method of manufacturing the MCCL 1 according to an example embodiment of the present inventive concept will be described with reference to FIGS. 5A through 9. FIGS. 5A through 9 are views schematically illustrating sequential processes of a method of manufacturing an MCCL according to an example embodiment of the present inventive concept.

First, as illustrated in FIGS. 5A and 5B, a metal base 10 having a quadrangular structure having a desired size may be prepared, and at least one recess 11 may be formed in one surface of the metal base 10.

The metal base 10 may be a copper plate formed of copper (Cu) having excellent heat conductivity. The at least one recess 11 may be formed by partially etching a surface of the metal base 10 to have a desired depth. In particular, since the metal base 10 is formed of copper (Cu), the recess 11 may be easily formed through etching.

The recess 11 may be formed to have, for example, a cup shaped structure in which inner surfaces thereof are sloped or inclined toward a bottom surface thereof. Alternatively, the recess 11 may also be formed to have a step structure in which the inner surfaces thereof are perpendicular to the bottom surface thereof.

Meanwhile, a process of coating a reflective layer 40 to cover a surface of the recess 11 may be performed. The reflective layer 40 may be a thin film formed by coating any one of Ag, Al, and TiO₂. The reflective layer 40 may be optional, and thus, the process of coating the reflective layer 40 may be omitted according to an example embodiment of the present inventive concept.

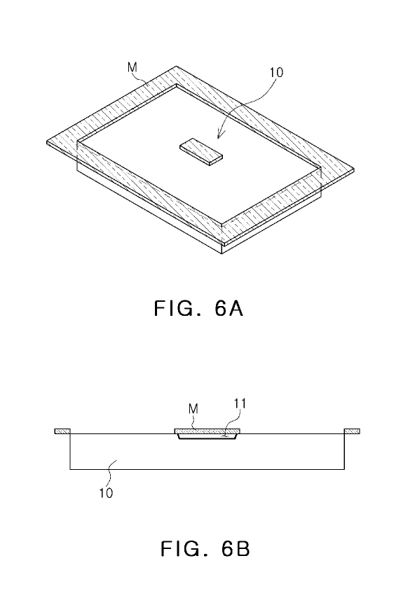

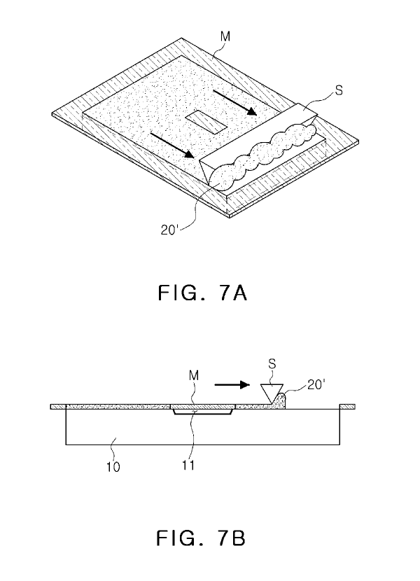

FIGS. 6A through 7B schematically illustrate processes of forming the insulating layer 20 on one surface of the metal base 10 in a laminating manner. The insulating layer 20 may have a first opening 21 and may be laminated on the metal base 10 such that the recess 11 is exposed through the first opening 21.

The insulating layer 20 may be formed, for example, through a printing method using a mask M (see FIG. 6A). As illustrated in FIGS. 6A and 6B, the mask M covering the recess 11 may be disposed on one surface of the metal base 10. As illustrated in FIGS. 7A and 7B, an insulating material 20′ may be applied to the mask M by using a squeegee S, or the like, so as to be printed. Thereafter, the insulating material 20′ may be cured to form the insulating layer 20.

An upper region of the recess 11 covered by the mask M so the insulating layer 20 is not formed thereon may form the first opening 21 exposing the recess 11 when the mask M is removed. The first opening 21 may have shape and size substantially corresponding to shape and size of the region opened from one surface of the recess 11. The first opening 21 may be variously formed corresponding to the number and positions of recesses 11.

The insulating layer 20 may be formed of an insulating resin material such as an epoxy-based resin or a polyimide resin.

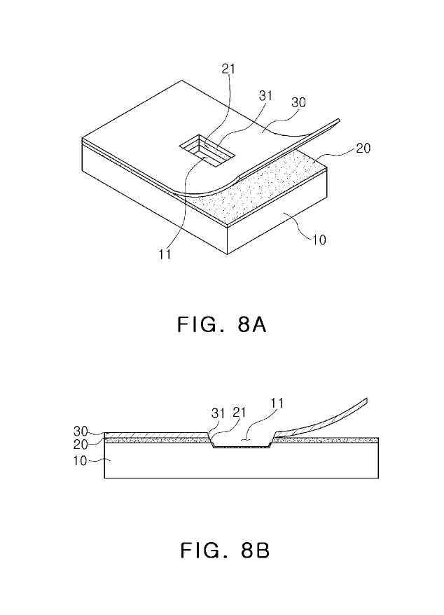

FIGS. 8A and 8B schematically illustrate a process of laminating the copper foil 30 on the insulating layer 20. The copper foil 30 may have a shape corresponding to a shape of the insulating layer 20 to cover the insulating layer 20, and may be attached to the insulating layer 20.

The copper foil 30 may have a second opening 31, and thus, when the copper foil 30 is laminated on the insulating layer 20, the recess 11 and the first opening 21 may be exposed through the second opening 31. The second opening 31 may have a shape substantially corresponding to a shape of the first opening 21.

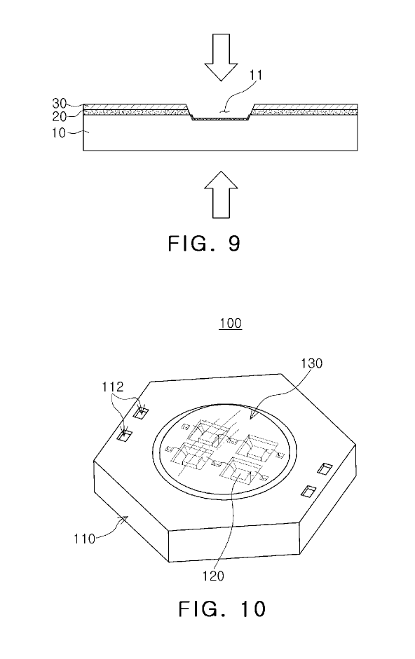

In a state in which the insulating layer 20 and the copper foil 30 are laminated on the metal base 10, the insulating layer 20 and the copper foil 30 may be bonded through hot pressing, forming an MCCL, as illustrated in FIG. 9.

Meanwhile, a process of exposing the insulating layer 20 from the circumferential edges of the copper foil 30 may be performed after or before the hot pressing process. In this case, the insulating layer 20 may be exposed by partially removing the circumferential edge portions of the copper foil 30. The copper foil 30 may be removed through etching or may be exfoliated. Alternatively, copper foil 30 having a size smaller than a size of the insulating layer 20 may be used, and in this case, the insulating layer 20 may be exposed without having to removing the copper foil 30.

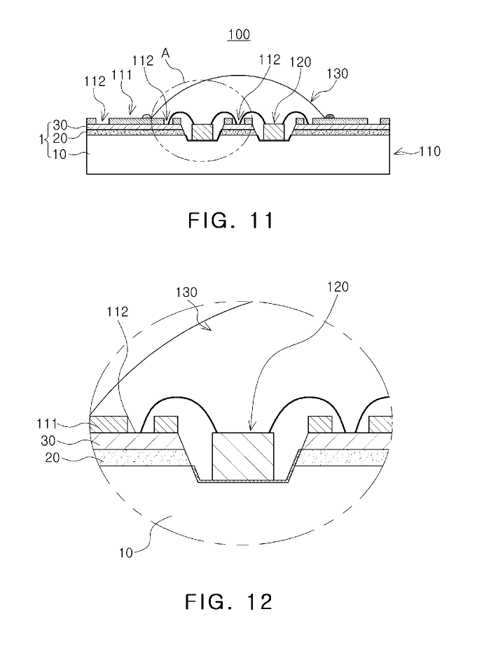

FIGS. 10 through 12 schematically illustrate a light source module 100 according to an example embodiment of the present inventive concept. FIG. 10 is a perspective view schematically illustrating an example of a light source module using an MCCL according to various example embodiments of the present inventive concept, FIG. 11 is a cross-sectional view of the MCCL of FIG. 10, and FIG. 12 is an enlarged view of portion “A” of FIG. 11.

The light source module 100 according to an example embodiment of the present inventive concept may have a chip on board (COB) type structure and may include a board 110, a plurality of light emitting devices 120 mounted on the board 110, and an encapsulator 130.

The board 110 may be formed of a material having excellent heat conductivity to enhance heat dissipation characteristics. For example, the board 110 may be an MCPCB. The board 110 may be formed by using the MCCL 1 described above with reference to FIGS. 1 through 9.

Circuit wirings for electrical connection with the light emitting devices 120 may be formed by patterning the copper foil 30 of the MCCL 1. The copper foil 30 may be covered by a photo solder resist (PSR) 111 coated thereon so as to protect the copper foil 30. An exposed portion of the copper foil 30 not covered by the PSR 111 coated thereon may define electrode pads 112 electrically connected to the light emitting devices 120. Also, the second opening 31 (see FIG. 8B) of the copper foil 30, the first opening 21 (see FIG. 8B) of the insulating layer 20, and the recess 11 (see FIG. 8B) of the metal base 10 may be exposed outwardly without being covered by the PSR 111.

The light emitting devices 120 may be a type of photoelectronic device generating light having a predetermined wavelength by externally applied driving power. Typically, the light emitting devices 120 may be semiconductor light emitting diode (LED) chips including semiconductor layers epitaxially grown on a growth substrate. The LED chips may emit blue light, green light, or red light, or may emit white light, depending on a material contained therein or phosphors coated thereon.

A single or a plurality of light emitting device 120 may be mounted on the board 110. In detail, the light emitting device(s) 120 may be directly mounted on the metal base 10 within the recesses of the metal base 10. Namely, in the related art, the light emitting device 120 is mounted on the copper foil 30, and thus, the insulating layer 20 and the copper foil 30 are interposed between the metal base 10 and the light emitting device 120. In the related art, therefore, heat generated by the light emitting device 120 is not directly transmitted to the metal base 10 due to the insulating layer 20, degrading heat dissipation efficiency. In contrast, in an example embodiment of the present inventive concept, since the light emitting device 120 may be directly mounted on the metal base 10, penetrating through the copper foil 30 and the insulating layer 20, heat from the light emitting device 120 may be directly transmitted (conducted) to the metal base 10, thus enhancing heat dissipation efficiency.

Also, unlike the related art in which the light emitting device 120 is mounted to protrude from the copper foil 30, in an example embodiment of the present inventive concept, since the light emitting device 120 may be mounted in a position depressed to a predetermined depth from a surface of the metal base 10 (namely, the bottom surface of the recess 11), penetrating through the copper foil 30 and the insulating layer 20, the mounting position of the light emitting device 120 may be lowered to reduce a size of the light emitting module 100. This is advantageous to miniaturization of a product.

When a plurality of light emitting devices 120 are mounted, the plurality of light emitting devices 120 may be homogenous, emitting light having the same wavelength. Alternatively, the plurality of light emitting devices may also be configured to be heterogeneous emitting light having different wavelengths.

For example, the plurality of light emitting devices 120 may include a blue LED chip covered by a wavelength conversion layer containing a phosphor to emit white light. The wavelength conversion layer may serve to convert a wavelength of light emitted from each light emitting device 120, and to this end, the wavelength conversion layer may have a structure in which at least one species of phosphor is dispersed in a transparent resin. Light having a wavelength converted by the wavelength conversion layer may be mixed with light emitted from the light emitting device 120 to implement a white light.

For example, when the light emitting device 120 is a blue LED chip emitting blue light, a yellow phosphor may be used. Besides, when the light emitting device 120 is a UV LED chip emitting ultraviolet light, red, green, and blue phosphors may be mixed to be used.

The encapsulator 130 may be formed of a light-transmissive material allowing the light generated by the plurality of light emitting devices 120 to be emitted externally. The light-transmissive material may be, for example, a resin such as silicon, epoxy, or the like.

The encapsulator 130 may be formed by injecting a resin onto the board 110 and curing the resin in a manner of heating, light irradiation, passage of time, and the like. Also, the encapsulator 130 may have various shapes to adjust an angle of beam spread of light emitted outwardly. For example, the encapsulator 130 may have an upwardly convex dome shape or a flat structure with a flat upper portion. Also, the encapsulator 130 may have a polygonal shape.

The encapsulator 130 may contain at least one or more species of wavelength conversion material, e.g., phosphor, emitting light having a different wavelength upon being excited by light generated by the light emitting device 120, whereby light of various colors may be emitted. Also, in order to diffuse externally emitted light, a light reflective material may be contained. The light reflective material may be, for example, SiO₂, TiO₂, Al₂O₃, or the like.

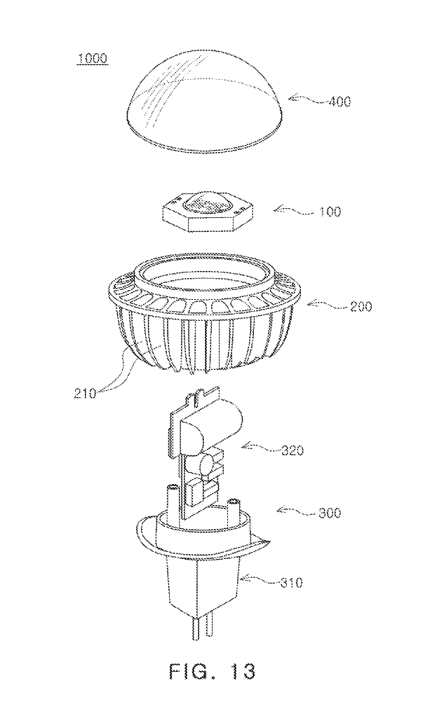

FIG. 13 is a perspective view schematically illustrating a lighting device according to an example embodiment of the present inventive concept.

Referring to FIG. 13, a lighting device 1000 according to an example embodiment of the present inventive concept may be a bulb-type lamp and may be used as an indoor lighting device, for example, a downlight. The lighting device 1000 may include a base 200 having an electricity connection structure 300 and at least one light source module 100 mounted on the base 200. The lighting device 1000 may further include a cover unit 400 covering the light source module 100.

The light source module 100 may be substantially identical to the light source module 100 illustrated in FIGS. 10 through 12, and thus, a detailed description thereof will be omitted. In an example embodiment of the present inventive concept, a single light source module 100 may be installed on the base 200, but if necessary, a plurality of light source modules 100 may be installed.

The base 200 may serve both as a frame supporting the light source module 100 and as a heat sink outwardly dissipating heat generated by the light source module 100. To this end, the base 200 may be formed of a material being substantially robust and having high heat conductivity. For example, the base 200 may be formed of a metal such as aluminum (Al), or a heat dissipation resin.

A plurality of heat dissipation fins 210 may be provided in an outer surface of the base 200 in order to increase a contact area with air to enhance heat dissipation efficiency.

The base 200 may have the electricity connection structure 300 electrically connected to the light source module 100. The electricity connection structure 300 may include a terminal unit 310 and a driving unit 320 supplying driving power supplied through the terminal unit 310 to the light source module 100.

The terminal unit 310 may allow the lighting device 1000 to be fixedly installed in, for example, a socket, or the like, so as to be electrically connected. In an example embodiment of the present inventive concept, the terminal unit 310 may have a slidably inserted pin-type structure, but the present disclosure is not limited thereto. If necessary, the terminal unit 310 may have an Edison type structure having thread going around to be inserted.

The driving unit 320 may convert external driving power into a current source appropriate for driving the light source module 100, and provide the same. The driving unit 320 may be configured as, for example, an AC-DC converter, a rectifying circuit component, a fuse, or the like. Also, the driving unit 320 may further include a communications module implementing remote controlling according to circumstances.

The cover unit 400 may be installed on the base 200 to cover the light source module 100 and have a convex lens shape or a bulb shape. The cover unit 400 may be formed of a light-transmissive material and contain a light diffusion material.

As described above, the lighting device 1000 using a light emitting device may be applied to an indoor lighting device or an outdoor lighting device according to the purpose thereof. Examples of the indoor LED lighting device may include a lamp, a fluorescent lamp (LED-tube), or a flat panel type lighting device replacing an existing lighting fixture (retrofit), and examples of the outdoor LED lighting device may include a streetlight, a security light, a flood light, a scene lamp, a traffic light, and the like.

Also, the lighting device using LEDs may be utilized as an internal or external light source of a vehicle. As an internal light source, the LED lighting device may be used as an indoor light, a reading light, or as various dashboard light sources of a vehicle. As an external light source, the LED lighting device may be used as a headlight, a brake light, a turn signal lamp, a fog light, a running light, and the like.

In addition, the LED lighting device may also be applicable as a light source used in robots or various mechanic facilities. LED lighting using light within a particular wavelength band may promote plant growth and stabilize a person's mood or treat diseases using emotional lighting.

The lighting device using a light emitting may be altered in terms of an optical design thereof according to a product type, a location, and a purpose. For example, in relation to the foregoing emotional illumination, a technique for controlling lighting by using a wireless (remote) control technique utilizing a portable device such as a smartphone may be provided, in addition to the technique of controlling color, temperature, brightness, and hue of illumination

In addition, a visible wireless communications technology aimed at simultaneously achieving a unique purpose of an LED light source and a purpose of a communications unit by adding a communications function to LED lighting devices and display devices may be available. This is because an LED light source has a longer lifespan and excellent power efficiency, implements various colors, supports a high switching rate for digital communications, and is available for digital control, in comparison with existing light sources.

The visible light wireless communications technology is a wireless communications technology transferring information wirelessly by using light having a visible light wavelength band recognizable by the naked eye. The visible light wireless communications technology is distinguished from a wired optical communications technology in that it uses light having a visible light wavelength band and that a communications environment is based on a wireless scheme.

Also, unlike RF wireless communications, the visible light wireless communications technology has excellent convenience and physical security properties as it can be freely used without being regulated or needing permission in the aspect of frequency usage, and is differentiated in that a user can physically check a communications link. Above all, the visible light wireless communications technology is a fusion technique to have features of obtaining both a unique purpose as a light source and a communications function.

As set forth above, according to example embodiments of the present inventive concept, a metal copper clad laminate (MCCL) contributing to reduction in size of a package module when applied thereto, while enhancing heat dissipation efficiency and a method of manufacturing the same may be provided.

Advantages and effects of the present disclosure are not limited to the foregoing content and any other technical effects not mentioned herein may be easily understood by a person skilled in the art from the foregoing description.

While example embodiments of the present inventive concept have been shown and described above, it will be apparent to those skilled in the art that modifications and variations could be made without departing from the spirit and scope of the present disclosure as defined by the appended claims.

What is claimed is:

1. A metal copper clad laminate (MCCL), comprising:
a metal base having at least one recess defined in one surface thereof;
an insulating layer laminated on the one surface of the metal base and having a first opening exposing the at least one recess; and
a copper foil laminated on the insulating layer and having a second opening exposing the at least one recess and the first opening.

2. The metal copper clad laminate of claim 1, wherein the first opening has shape and size substantially corresponding to shape and size of a region opened from the one surface of the at least one recess.

3. The metal copper clad laminate of claim 1, wherein the second opening has a shape substantially corresponding to a shape of the first opening.

4. The metal copper clad laminate of claim 1, wherein the recess has a cup structure in which inner surfaces of the at least one recess are sloped toward a bottom surface thereof.

5. The metal copper clad laminate of claim 1, further comprising a reflective layer covering a surface of the at least one recess.

6. The metal copper clad laminate of claim 5, wherein the reflective layer is at least one selected from the group consisting of an Ag thin film, an Al thin film, and a TiO₂ thin film.

7. The metal copper clad laminate of claim 1, wherein the metal base is a copper plate.

8. The metal copper clad laminate of claim 1, wherein the copper foil has a size smaller than a size of the insulating layer, and exposes the insulating layer along circumferential edges of the copper foil.

9. A method of manufacturing a metal copper clad laminate (MCCL), the method comprising:
forming at least one recess on one surface of a metal base;
forming an insulating layer on the one surface of the metal base to have a first opening exposing the at least one recess therethrough; and
forming a copper foil on the insulating layer to have a second opening exposing the at least one recess and the first opening therethrough.

10. The method of claim 9, wherein the metal base is a copper plate.

11. The method of claim 9, wherein the forming of at least one recess comprises partially etching a surface of the metal base to a depth.

12. The method of claim 9, wherein the forming of the insulating layer comprises:
disposing a mask covering the at least one recess on the one surface of the metal base; and
applying an insulating material to the mask to print the insulating material.

13. The method of claim 9, wherein the first opening has shape and size substantially corresponding to shape and size of an open region of the at least one recess, and the second opening has a shape substantially corresponding to a shape of the first opening.

14. The method of claim 9, further comprising coating a reflective layer to cover a surface of the at least one recess.

15. The method of claim 9, further comprising exposing the insulating layer along circumferential edges of the copper foil.

16. A light source module having a chip on board (COB) type structure, comprising:
a board having the MCCL of claim 1;
a light emitting device disposed in direct contact with an exposed portion of the at least one recess of the MCCL; and
an encapsulator disposed on the light emitting device.

17. The light source module of claim 16, further comprising a photo solder resist (PSR) coated on the copper foil of the MCCL,
wherein an exposed portion of the copper foil not coated with the PSR defines electrode pads that are electrically connected to the light emitting device.

18. A method of manufacturing a metal copper clad laminate (MCCL), the method comprising:
laminating an insulating layer on a metal base that has at least one recess and forming a first opening in the insulating layer to expose the at least one recess through the first opening;
laminating a copper foil on the insulating layer and forming a second opening in the copper foil to expose the at least one recess and the first opening through the second opening; and
bonding the copper foil and the insulating layer through hot pressing.

19. The method of claim 18, further comprising exposing the insulating layer along circumferential edges of the copper foil before the hot pressing.

20. The method of claim 18, further comprising exposing the insulating layer along circumferential edges of the copper foil after the hot pressing.
